(19) United States
(12) Patent Application Publication
(10) Pub. No.: US 2024/0224772 A1
(43) Pub. Date: Jul. 4, 2024

(54) DISPLAY DEVICE

(71) Applicant: LG Display Co., Ltd., Seoul (KR)

(72) Inventors: JaeHyung JO, Goyang-si (KR); YoungMin JEONG, Paju-si (KR); InYeong KONG, Seoul (KR)

(73) Assignee: LG Display Co., Ltd., Seoul (KR)

(21) Appl. No.: 18/242,359

(22) Filed: Sep. 5, 2023

(30) Foreign Application Priority Data
Dec. 30, 2022 (KR) 10-2022-0190568

(51) Int. Cl. H10K 71/00; H10K 59/131

(52) U.S. Cl. CPC H10K 71/861; H10K 59/131

(57) ABSTRACT

A display device can include a plurality of sub pixels disposed on a substrate including an emission area and a non-emission area; a gate line disposed in the non-emission area, the gate line extending in a first direction; at least one signal line disposed in the non-emission area, the at least one signal line overlapping with the gate line; at least one branch line connected to the at least one signal line; and a repair part overlapping with the at least one branch line, the repair part being spaced apart from the at least one branch line. Also, the repair part can reflect laser light onto a portion of the least one branch line overlapping with the repair part and cut the least one branch line to deactivate one of the plurality of sub pixels.

### CROSS-REFERENCE TO RELATED APPLICATIONS

This application claims priority to Korean Patent Application No. 10-2022-0190568 filed on Dec. 30, 2022, in the Republic of Korea, the entirety of which is incorporated herein by reference.

### BACKGROUND

### Field

The present disclosure relates to a display device, and more particularly, to a display device which is capable of stably repairing defects while implementing a high aperture ratio.

### Description of the Related Art

Currently, as society enters a full-scale information era, a field of a display device which visually expresses electrical information signals has been rapidly developed and studies are continuing to improve the performance of various display devices in different areas, such as thin-thickness, light weight, and low power consumption.

A representative display device can include a liquid crystal display (LCD) device, a field emission display (FED) device, an electro-wetting display (EWD) device, an organic light emitting display (OLED) device, and the like.

Among them, the organic light emitting display device is a self-emitting display device so that a separate light source is not necessary (e.g., no backlight unit is needed), which is different from the liquid crystal display device. Therefore, the organic light emitting display device can be manufactured to have a light weight and a small thickness. Further, since the organic light emitting display device is advantageous not only in terms of power consumption due to the low voltage driving, but also in terms of color implementation, a response speed, a viewing angle, and a contrast ratio (CR), it is expected to be utilized in various fields.

Also, during the manufacturing process of the display device, one or more sub pixels may become defective and remain in an always on state or an impaired state, which can impair image quality. Thus, a need exists for an efficient way to be able to repair or deactivate a defective pixel that does not reduce the size of the emission area or introduce undesirable parasitic capacitance and allows for more freedom in design choice.

### SUMMARY OF THE DISCLOSURE

An object to be achieved by the present disclosure is to provide a display device with an improved aperture ratio by configuring a branch line with a transparent material.

Another object to be achieved by the present disclosure is to provide a display device which performs a repair process without additionally individually disposing a metal layer in a branch line.

Still another object to be achieved by the present disclosure is to provide a display device which performs a repair process without degrading the aperture ratio.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device includes a substrate in which an emission area and a non-emission area are included and a plurality of sub pixels is defined, at least one gate line which is in the non-emission area and extends in one direction, at least one signal line which is in the non-emission area and intersects the at least one gate line, at least one branch line which is connected to the at least one signal line and a repair unit which overlaps the at least one branch line.

Other detailed matters of the example embodiments are included in the detailed description and the drawings.

According to the present disclosure, a branch line extending from the signal line is configured by a semiconductor layer and a transparent oxide layer so that transparency is provided to ensure a wider opening area.

According to the present disclosure, the repair process can be stably performed on the signal line while ensuring a high aperture ratio.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic block diagram of a display device according to an embodiment of the present disclosure;

FIG. 2 is a circuit diagram of a sub pixel of a display device according to an embodiment of the present disclosure.

FIG. 3 is an enlarged plan view of a display device according to an embodiment of the present disclosure.

FIG. 4 is an enlarged view of an area A of FIG. 3 according to an embodiment of the present disclosure.

FIGS. 5A and 5B are cross-sectional views taken along the line V-V′ of FIG. 4 according to embodiments of the present disclosure.

FIGS. 6A to 6H are plan views sequentially illustrating a manufacturing process of a display device according to an embodiment of the present disclosure;

FIG. 7 is an enlarged plan view of a display device according to another example embodiment of the present disclosure.

FIG. 8 is an enlarged view of an area B of FIG. 7 according to an embodiment of the present disclosure;

FIGS. 9A and 9B are cross-sectional views taken along the line IX-IX′ of FIG. 8 according to embodiments of the present disclosure;

FIG. 10 is an enlarged plan view of a display device according to still another embodiment of the present disclosure.

FIG. 11 is an enlarged view of an area C of FIG. 10 according to an embodiment of the present disclosure; and

FIGS. 12A and 12B are cross-sectional views taken along the line XII-XII′ of FIG. 11 according to embodiments of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only.” Any references to singular can include plural unless expressly stated otherwise.

Components are interpreted to include an ordinary error range even if not expressly stated.

When the position relation between two parts is described using the terms such as “on,” “above,” “below,” and “next,” one or more parts can be positioned between the two parts unless the terms are used with the term “immediately” or “directly.”

When an element or layer is disposed “on” another element or layer, another layer or another element can be interposed directly on the other element or therebetween.

Although the terms “first,” “second,” and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

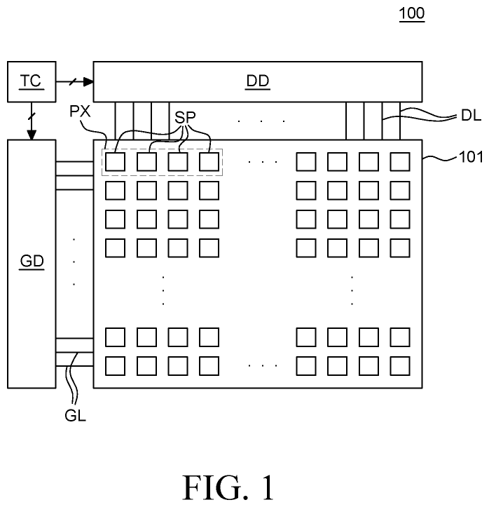

FIG. 1 is a schematic block diagram of a display device according to an example embodiment of the present disclosure. Referring to FIG. 1, a display device 100 includes a display panel 101, a gate driver GD, a data driver DD, and a timing controller TC.

The display panel 101 is a panel for displaying images. The display panel 101 can include various circuits, wiring lines, and light emitting diodes disposed on the substrate. The display panel 101 is divided by a plurality of data lines DL and a plurality of gate lines GL intersecting each other and can include a plurality of pixels PX connected to the plurality of data lines DL and the plurality of gate lines GL. The display panel 101 can include a display area defined by a plurality of pixels PX and a non-display area in which various signal lines or pads are formed. The display panel 101 can be implemented by a display panel 101 used in various display devices, such as a liquid crystal display device, an organic light emitting display device, or an electrophoretic display device. Hereinafter, it is described that the display panel 101 is a panel used for the organic light emitting display device, but is not limited thereto.

The timing controller TC receives timing signals such as a vertical synchronization signal, a horizontal synchronization signal, a data enable signal, or a dot clock by means of a receiving circuit such as an LVDS or TMDS interface connected to a host system. The timing controller TC generates timing control signals based on the input timing signal to control the data driver DD and the gate driver GD.

The data driver DD supplies a data voltage to the plurality of sub pixels SP. The data driver DD can include a plurality of source drive ICs (integrated circuits). The plurality of source drive ICs can be supplied with digital video data and a source timing control signal from the timing controller TC. The plurality of source drive ICs converts digital video data into a gamma voltage in response to the source timing control signal to generate a data voltage DATA and can supply the data voltage through the data line DL of the display panel 101. The plurality of source drive ICs can be connected to the data line DL of the display panel 101 by a chip on glass (COG) process or a tape automated bonding (TAB) process. Further, the source drive ICs are formed on the display panel 101 or are formed on a separate PCB substrate to be connected to the display panel 101.

The gate driver GD supplies a gate signal to the plurality of sub pixels SP. The gate driver GD can include a level shifter and a shift register. The level shifter shifts a level of a clock signal input at a transistor-transistor-logic (TTL) level from the timing controller TC and then supplies the clock signal to the shift register. The shift register can be formed in the non-display area of the display panel 101, by a GIP manner, but is not limited thereto. The shift register can be configured by a plurality of stages which shifts the gate signal to output, in response to the clock signal and the driving signal. The plurality of stages included in the shift register can sequentially output the gate signal through a plurality of output terminals.

The display panel 101 can include a plurality of sub pixels SP. The plurality of sub pixels SP can be sub pixels SP for emitting different color light. For example, the plurality of sub pixels SP can be a red sub pixel, a green sub pixel, a blue sub pixel, and a white sub pixel, but is not limited thereto. The plurality of sub pixels SP can configure a pixel PX. That is, the red sub pixel, the green sub pixel, the blue sub pixel, and the white sub pixel can configure one pixel PX and the display panel 101 can include a plurality of pixels PX.

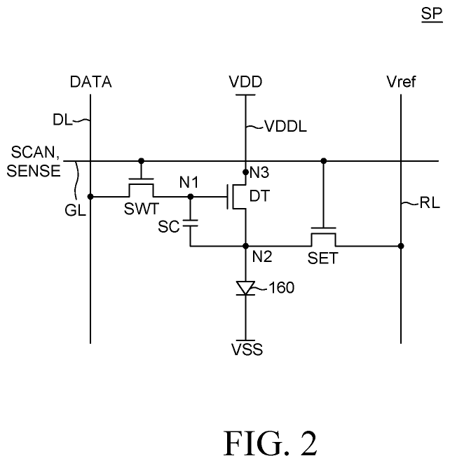

Hereinafter, a driving circuit for driving one sub pixel SP will be described in more detail with reference to FIG. 2 together.

FIG. 2 is a circuit diagram of a sub pixel of a display device according to an example embodiment of the present disclosure. In FIG. 2, a circuit diagram for one sub pixel SP among the plurality of sub pixels SP of the display device 100 is illustrated.

Referring to FIG. 2, the sub pixel SP can include a switching transistor SWT, a sensing transistor SET, a driving transistor DT, a storage capacitor SC, and a light emitting diode 160.

The light emitting diode 160 can include an anode, an organic layer, and a cathode. The organic layer can include various organic layers such as a hole injection layer, a hole transport layer, an organic emission layer, an electron transport layer, and an electron injection layer. The anode of the light emitting diode 160 can be connected to an output terminal of the driving transistor DT and a low potential voltage VSS is applied to the cathode. Even though in FIG. 2, it is described that the light emitting diode 160 is an organic light emitting diode, the present disclosure is not limited thereto so that as the light emitting diode 160, an inorganic light emitting diode, that is, an LED can also be used.

Referring to FIG. 2, the switching transistor SWT is a transistor which transmits the data voltage DATA to a first node N1 corresponding to a gate electrode of the driving transistor DT. The switching transistor SWT can include a drain electrode connected to the data line DL, a gate electrode connected to the gate line GL, and a source electrode connected to the gate electrode of the driving transistor DT. The switching transistor SWT is turned on by a scan signal SCAN applied from the gate line GL to transmit a data voltage DATA supplied from the data line DL to the first node N1 corresponding to the gate electrode of the driving transistor DT.

Referring to FIG. 2, the driving transistor DT is a transistor which supplies a driving current to the light emitting diode 160 to drive the light emitting diode 160. The driving transistor DT can include a gate electrode corresponding to the first node N1, a source electrode corresponding to a second node N2 and an output terminal, and a drain electrode corresponding to a third node N3 and an input terminal. The gate electrode of the driving transistor DT is connected to the switching transistor SWT, the drain electrode is applied with a high potential voltage VDD by means of a high potential powerline VDDL, and the source electrode can be connected to the anode of the light emitting diode 160.

Referring to FIG. 2, a storage capacitor SC is a capacitor which maintains a voltage corresponding to the data voltage DATA for one frame. One electrode of the storage capacitor SC can be connected to the first node N1 and the other electrode can be connected to the second node N2.

In the meantime, in the display device 100, as the driving time of each sub pixel SP is increased, the circuit element such as the driving transistor DT can become degraded overtime. Accordingly, a unique characteristic value of the circuit element such as a driving transistor DT can be changed. Here, the unique characteristic value of the circuit element can include a threshold voltage Vth of the driving transistor DT or a mobility α of the driving transistor DT. For example, the threshold voltage Vth or the mobility α of the driving transistor DT can start to drift over time as the device remains in operation. The change in the characteristic value of the circuit element can cause a luminance change of the corresponding sub pixel SP. Accordingly, the change in the characteristic value of the circuit element can be used as the same concept as the luminance change of the sub pixel SP.

Further, the degree of the change in the characteristic values between circuit elements of each sub pixel SP can vary depending on a degree of degradation of each circuit element. Such a difference in the changed degree of the characteristic values between the circuit elements can cause a luminance deviation between the sub pixels SP, which can impair image quality. Accordingly, the characteristic value deviation between circuit elements can be used as the same concept as the luminance deviation between the sub pixels SP. The change in the characteristic values of the circuit elements, that is, the luminance change of the sub pixel SP and the characteristic value deviation between the circuit elements, that is, the luminance deviation between the sub pixels SP can cause problems such as the lowering of the accuracy for luminance expressiveness of the sub pixel SP or the presence of a screen abnormality.

Therefore, the sub pixel SP of the display device 100 according to the example embodiment of the present disclosure can provide a sensing function of sensing a characteristic value for the sub pixel SP and a compensating function of compensating for the characteristic value of the sub pixel SP using the sensing result.

Therefore, as illustrated in FIG. 2, the sub pixel SP can further include a sensing transistor SET to effectively control a voltage state of the source electrode of the driving transistor DT, in addition to the switching transistor SWT, the driving transistor DT, the storage capacitor SC, and the light emitting diode 160.

Referring to FIG. 2, the sensing transistor SET is connected between the source electrode of the driving transistor DT and the reference line RL which supplies a reference voltage Vref and a gate electrode is connected to the gate line GL. Therefore, the sensing transistor SET is turned on by the sensing signal SENSE applied through the gate line GL to apply the reference voltage Vref which is supplied through the reference line RL to the source electrode of the driving transistor DT. Further, the sensing transistor SET can be utilized as one of voltage sensing paths for the source electrode of the driving transistor DT.

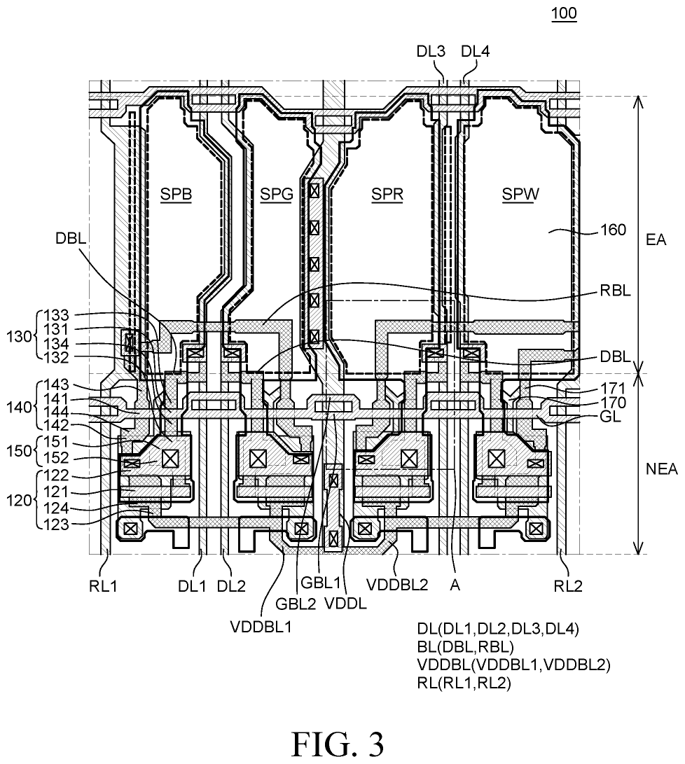

Referring to FIG. 2, the switching transistor SWT and the sensing transistor SET of the sub pixel SP can share one gate line GL. That is, the switching transistor SWT and the sensing transistor SET are connected to the same gate line GL to be applied with the same gate signal. However, for the convenience of description, a voltage which is applied to the gate electrode of the switching transistor SWT is referred to as a scan signal SCAN and a voltage which is applied to the gate electrode of the sensing transistor SET is referred to as a sensing signal SENSE. However, the scan signal SCAN and the sensing signal SENSE applied to one sub pixel SP are the same signals which are transmitted from the same gate line GL. Therefore, in FIG. 3, the scan signal SCAN and the sensing signal SENSE are defined and described as gate signals GATE1, GATE2, GATE3, and GATE4.

However, the present disclosure is not limited thereto so that only the switching transistor SWT is connected to the gate line GL and the sensing transistor SET can be connected to a separate sensing line. Therefore, the scan signal SCAN can be applied to the switching transistor SWT through the gate line GL and the sensing signal SENSE can be applied to the sensing transistor SET through the sensing line.

Accordingly, the reference voltage Vref is applied to the source electrode of the driving transistor DT by means of the sensing transistor SET. Further, a voltage for sensing the threshold voltage Vth of the driving transistor DT or the mobility α of the driving transistor DT is detected by the reference line RL. Further, the data driver DD can compensate for the data voltage DATA in accordance with a variation of the threshold voltage Vth of the driving transistor DT or the mobility a of the driving transistor DT.

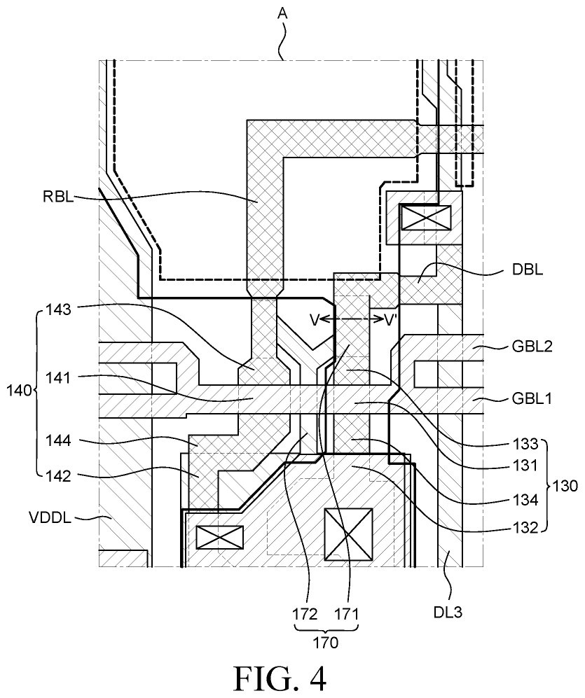

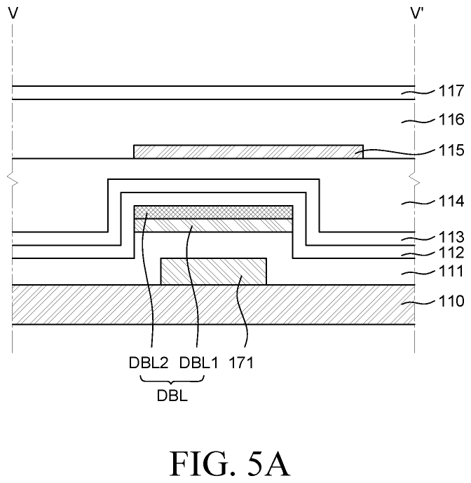

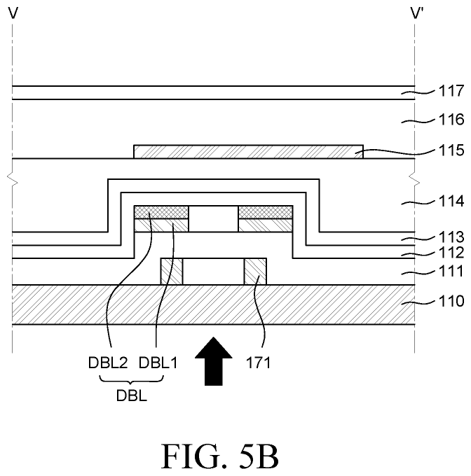

FIG. 3 is an enlarged plan view of a display device according to an example embodiment of the present disclosure. FIG. 4 is an enlarged view of an area A of FIG. 3 according to an embodiment of the present disclosure. FIGS. 5A and 5B are cross-sectional views taken along the line V-V′ of FIG. 4 according to embodiments of the present disclosure.

Referring to FIGS. 3 and 5B, a display device 100 according to an example embodiment of the present disclosure includes a substrate 110, a gate line GL, a data line DL, a high potential power line VDDL, a reference line RL, a light emitting diode 160, a first transistor 120, a second transistor 130, a third transistor 140, a storage capacitor 150, a color filter, a buffer layer 111, a gate insulating layer 112, a passivation layer 113, a planarization layer 114, an anode 115, a bank 116, and an emission layer 117. In FIG. 4, for the convenience of description, only the third transistor 140, a data line DL3, the gate line GL, the high potential power line VDDL, a data branch line DBL, a reference branch line RBL, and a repair unit 170 are illustrated. In FIGS. 5A and 5B, only a configuration from the substrate 110 to the emission layer 117, among various components of the display device 100 is illustrated for the convenience of description. FIGS. 5A and 5B are cross-sectional views of a red sub pixel SPR, but a cross-sectional structure of the red sub pixel SPR can be substantially the same as the cross-sectional structures of a white sub pixel SPW, a blue sub pixel SPB and a green sub pixel SPG.

First, referring to FIG. 3, the plurality of sub pixels SP include a blue sub pixel SPB, a green sub pixel SPG, a red sub pixel SPR, and a white sub pixel SPW, and each sub pixel SP includes an emission area EA and a non-emission area NEA.

The emission area EA is an area where one color of light is independently emitted and the light emitting diode 160 can be disposed therein. An emission area EA of the blue sub pixel SPB can be a blue emission area which emits blue light, an emission EA of the green sub pixel SPG can be a green emission area which emits green light, an emission area EA of the red sub pixel SPR can be a red emission area which emits red light, and an emission area EA of the white sub pixel SPW can be a white emission area which emits white light.

The non-emission area NEA is an area in which a driving circuit for driving the plurality of light emitting diodes 160 is disposed and for example, the first transistor 120, the second transistor 130, the third transistor 140, and the storage capacitor 150 can be disposed.

In the meantime, the non-emission areas NEA of the blue sub pixel SPB, the green sub pixel SPG, the red sub pixel SPR, and the white sub pixel SPW can have substantially similar structure. However, a plurality of sub pixels SP which configures one pixel PX shares signal lines to have different structures for every sub pixel. Referring to FIG. 3, the blue sub pixel SPB, the green sub pixel SPG, the red sub pixel SPR, and the white sub pixel SPW share a high potential power line VDDL. The blue sub pixel SPB and the green sub pixel SPG share a first reference line RL1 and the red sub pixel SPR and the white sub pixel SPW share a second reference line RL2. Accordingly, the blue sub pixel SPB and the green sub pixel SPG form one pair and the red sub pixel SPR and the white sub pixel SPW form one pair to be disposed with a symmetric structure.

Referring to FIG. 3 together, the high potential power line VDDL, the plurality of data lines DL, and the plurality of reference lines RL extending in a column direction (a Y axis direction) are disposed between the plurality of sub pixels SP on the substrate 110. The high potential power line VDDL, the plurality of data lines DL, and the plurality of reference lines RL can be disposed on the same layer of the substrate 110 and formed of the same material. For example, the high potential power line VDDL, the plurality of data lines DL, and the plurality of reference lines RL can be configured by a conductive material, such as copper (Cu), aluminum (Al), molybdenum (Mo), nickel (Ni), titanium (Ti), chrome (Cr), or an alloy thereof, but are not limited thereto.

The high potential power line VDDL is a wiring line which transmits a power signal to each of the plurality of sub pixels SP. The plurality of sub pixels SP which form one pixel can share one high potential power line VDDL. For example, the high potential power line VDDL is disposed between the green sub pixel SPG and the red sub pixel SPR to transmit a power signal to first transistors 120 of the blue sub pixel SPB and the green sub pixel SPG disposed at a left side of the high potential power line VDDL. Further, the high potential power line VDDL can transmit a power signal to first transistors 120 of the red sub pixel SPR and the white sub pixel SPW disposed at a right side of the high potential power line VDDL.

The plurality of data lines DL are lines which transmit a data signal to each of the plurality of sub pixels SP and include a first data line DL1, a second data line DL2, a third data line DL3, and a fourth data line DL4. The first data line DL1 is disposed between the blue sub pixel SPB and the green sub pixel SPG, that is, at a right side of the blue sub pixel SPB to transmit the data signal to the second transistor 130 of the blue sub pixel SPB. The second data line DL2 is disposed between the first data line DL1 and the green sub pixel SPG, that is, at a left side of the green sub pixel SPG to transmit the data signal to the second transistor 130 of the green sub pixel SPG. The third data line DL3 is disposed between the red sub pixel SPR and the white sub pixel SPW, that is, at a right side of the red sub pixel SPR to transmit the data signal to the second transistor 130 of the red sub pixel SPR. The fourth data line DL4 is disposed between the third data line DL3 and the white sub pixel SPW, that is, at a left side of the white sub pixel SPW to transmit the data signal to the second transistor 130 of the white sub pixel SPW.

The plurality of reference lines RL are wiring lines which transmit a reference signal to each of the plurality of sub pixels SP and include a first reference line RL1 and a second reference line RL2. Two sub pixels SP adjacent in the row direction (e.g., X-axis direction) can share one reference line RL. For example, the first reference line RL1 is disposed at a left side of the blue sub pixel SPB to transmit a reference voltage Vref to the third transistors 140 of the blue sub pixel SPB and the green sub pixel SPG. The second reference line RL2 is disposed at a right side of the white sub pixel SPW to transmit a reference voltage Vref to the third transistors 140 of the red sub pixel SPR and the white sub pixel SPW.

The first transistor 120 is disposed in the non-emission area NEA of each of the blue sub pixel SPB, the green sub pixel SPG, the red sub pixel SPR, and the white sub pixel SPW. The first transistor 120 includes a first gate electrode 121, a first source electrode 122, a first drain electrode 123, and a first active layer 124. The first transistor 120 which is electrically connected to the first electrode of light emitting diode 160 and the high potential power line VDDL can be a driving transistor DT.

First, the first drain electrode 123 is electrically connected to the high potential power line VDDL. Specifically, the first drain electrodes 123 of the blue sub pixel SPB, the green sub pixel SPG, the red sub pixel SPR, and the white sub pixel SPW can be electrically connected to the high potential power line VDDL. That is, the first drain electrodes 123 of the blue sub pixel SPB and the green sub pixel SPG can be integrally formed with the first high potential power branch line VDDBL1 extending from the high potential power line VDDL. The first drain electrodes 123 of the red sub pixel SPR and the white sub pixel SPW can be integrally formed with the second high potential power branch line VDDBL2 extending from the high potential power line VDDL.

The first active layer 124 can be formed of a semiconductor material, such as an oxide semiconductor, amorphous silicon, or polysilicon, but is not limited thereto. For example, when the first active layer 124 is formed of an oxide semiconductor, the first active layer 124 is formed by a channel region, a source region, and a drain region and becomes conductive to serve as a first source electrode 122 and a first drain electrode 123. Alternatively, a transparent oxide layer is further disposed in a partial area on the first active layer 124 to become conductive to serve as the first source electrode 122 and the first drain electrode 123. At this time, the transparent oxide layer can be configured by a transparent conductive material, such as tin oxide (TO), indium tin oxide (ITO), indium zinc oxide (IZO), or indium tin zinc oxide (ITZO), but is not limited thereto.

The gate insulating layer 112 is disposed on the first active layer 124. The gate insulating layer 112 can be a layer which insulates the first gate electrode 121 from the first active layer 124. The gate insulating layer 112 can be disposed only in an area corresponding to conductive layers which are formed of the same material as the first gate electrode 121 by the same process. For example, the gate insulating layer 112 is disposed on the entire surface of the substrate 110 and then removed together when the first gate electrode 121 and the conductive layers disposed on the gate insulating layer 112 are patterned. The gate insulating layer 112 can be configured by a single layer or a double layer of an insulating material such as silicon oxide SiOx or silicon nitride SiNx, but is not limited thereto.

The first gate electrode 121 can be disposed on the gate insulating layer 112 to overlap the channel region of the first active layer 124. The first gate electrode 121 can be configured by a conductive material, such as copper (Cu), aluminum (Al), molybdenum (Mo), nickel (Ni), titanium (Ti), chrome (Cr), or an alloy thereof, but is not limited thereto.

The second transistor 130 is disposed in the non-emission area NEA of each of the plurality of sub pixels SP. The second transistor 130 includes a second gate electrode 131, a second source electrode 132, a second drain electrode 133, and a second active layer 134. The second transistor 130 which is electrically connected to the gate line GL, the data line DL, and the first gate electrode 121 of the first transistor 120 can be a switching transistor SWT.

First, the second drain electrode 133 of each of the plurality of sub pixels SP is electrically connected to one data line DL among the plurality of data lines DL. The second drain electrode 133 is integrally formed with the plurality of data lines DL to be formed of the same material as the plurality of data lines DL. However, it is not limited thereto and as illustrated in FIG. 3, the second drain electrode 133 is connected to a data branch line DBL which is connected to the plurality of data lines DL through the contact hole and is disposed on the same layer and formed with the same material as the first drain electrode 123. Specifically, the second drain electrode 133 can be an area in which the second active layer 134 becomes conducive, similar to the first drain electrode 123.

The second source electrode 132 can be defined as the same layer as the second drain electrode 133. When the second source electrode 132 is part of the same layer as the second drain electrode 133, the second source electrode 132 can be an area in which the second active layer 134 becomes conductive, similar to the second drain electrode 133.

The second active layer 134 of each of the plurality of sub pixels SP can be formed of a semiconductor material, such as an oxide semiconductor, amorphous silicon, or polysilicon, but is not limited thereto. For example, when the second active layer 134 is formed of an oxide semiconductor, the second active layer 134 is formed by a channel region, a source region, and a drain region and becomes conductive to serve as a second source electrode 132 and a second drain electrode 133. In the meantime, a transparent oxide layer is further disposed in a partial area on the second active layer 134 to become conductive to serve as the second source electrode 132 and the second drain electrode 133. At this time, the transparent oxide layer can be configured by a transparent conductive material, such as tin oxide (TO), indium tin oxide (ITO), indium zinc oxide (IZO), or indium tin zinc oxide (ITZO), but is not limited thereto. The second gate electrode 131 can be disposed on the gate insulating layer 112 to overlap with the channel region of the second active layer 134. The second gate electrode 131 can be configured by a conductive material, such as copper (Cu), aluminum (Al), molybdenum (Mo), nickel (Ni), titanium (Ti), chrome (Cr), or an alloy thereof, but is not limited thereto.

The second gate electrode 131 can be the gate line GL. That is, a part of the gate line GL can serve as the second gate electrode 131. The gate line GL can be configured by a conductive material, such as copper (Cu), aluminum (Al), molybdenum (Mo), nickel (Ni), titanium (Ti), chrome (Cr), or an alloy thereof, but is not limited thereto.

The gate line GL transmits a gate signal to each of the plurality of sub pixels SP and extends in a row direction to traverse the plurality of sub pixels SP. For example, the gate line GL extends between the non-emission area NEA and the emission area EA of each of the plurality of sub pixels SP in the row direction to intersect the high potential power line VDDL, the plurality of data lines DL, and the plurality of reference lines RL extending in the column direction. A gate redundancy structure formed in the gate line GL will be described in detail below with reference to FIGS. 4 to 5B.

The third transistor 140 is disposed in the non-emission area NEA of each of the plurality of sub pixels SP. For example, the third transistor 140 and the second transistor 130 can be disposed adjacent to each other and connected to the same gate line GL. The third transistor 140 includes a third gate electrode 141, a third source electrode 142, a third drain electrode 143, and a third active layer 144. The third transistor 140 which is electrically connected to the reference line RL, the gate line GL, and the second capacitor electrode 152 of the storage capacitor 150 can be a sensing transistor SET.

First, the third drain electrode 143 is electrically connected to the reference line RL. Specifically, the third drain electrodes 143 of the blue sub pixel SPB and the green sub pixel SPG can be electrically connected to the first reference line RL1 and the third drain electrodes 143 of the red sub pixel SPR and the white sub pixel SPW can be electrically connected to the second reference line RL2. That is, the third drain electrodes 143 of the blue sub pixel SPB and the green sub pixel SPG can be integrally formed with the reference branch line RBL extending from the first reference line RL1. The third drain electrodes 143 of the red sub pixel SPR and the white sub pixel SPW can be integrally formed with the reference branch line RBL extending from the second reference line RL2. As illustrated in FIG. 3, the third drain electrode 143 can be integrally formed with the reference branch line RBL connected to the reference line RL through the contact hole to be formed with the same material. Specifically, the third drain electrode 143 can be an area in which the third active layer 144 becomes conducive, similar to the second drain electrode 133.

The third active layer 144 can be disposed in each of the plurality of sub pixels SP. The third active layer 144 can be formed of a semiconductor material, such as an oxide semiconductor, amorphous silicon, or polysilicon, but is not limited thereto. For example, when the third active layer 144 is formed of an oxide semiconductor, the third active layer 144 is formed by a channel region, a source region, and a drain region and becomes conductive to serve as a third source electrode 142 and a third drain electrode 143. Alternatively, a transparent oxide layer is further disposed in a partial area on the third active layer 144 to become conductive to serve as the third source electrode 142 and the third drain electrode 143. At this time, the transparent oxide layer can be configured by a transparent conductive material, such as tin oxide (TO), indium tin oxide (ITO), indium zinc oxide (IZO), or indium tin zinc oxide (ITZO), but is not limited thereto.

The gate insulating layer 112 can be disposed on the third active layer 144. The gate insulating layer 112 can be a layer which insulates the third gate electrode 141 from the third active layer 144. The gate insulating layer 112 can be disposed only in an area corresponding to conductive layers which are formed of the same material as the third gate electrode 141 by the same process. For example, the gate insulating layer 112 is disposed on the entire surface of the substrate 110 and then removed together when the third gate electrode 141 and the conductive layers disposed on the gate insulating layer 112 are patterned. For example, the gate insulating layer 112 can be configured by a single layer or a double layer of an insulating material, such as silicon oxide SiOx or silicon nitride SiNx, but is not limited thereto. The third gate electrode 141 is disposed on the gate insulating layer 112 to overlap the channel region of the third active layer 144. The third gate electrode 141 can be the gate line GL. That is, a part of the gate line GL can serve as the third gate electrode 141. The third gate electrode 141 can be configured by a conductive material, such as copper (Cu), aluminum (Al), molybdenum (Mo), nickel (Ni), titanium (Ti), chrome (Cr), or an alloy thereof, but is not limited thereto.

A storage capacitor 150 is disposed in the non-emission area NEA of each of the plurality of sub pixels SP. The storage capacitor 150 can store a voltage between the first gate electrode 121 and the first source electrode 122 of the first transistor 120 to allow the light emitting diode 160 to continuously maintain a constant state for one frame. The storage capacitor 150 includes a first capacitor electrode 151 and a second capacitor electrode 152.

The first capacitor electrode 151 can be a conductive area of the second active layer 134 in which the semiconductor layer and the transparent oxide layer are laminated on each other. The first capacitor electrode 151 can be electrically connected to the first gate electrode 121 through a contact hole formed in the buffer layer 111.

The second capacitor electrode 152 can be disposed on the substrate 110 to overlap with the first capacitor electrode 151. The second capacitor electrode 152 can be formed by electrically connecting a light shielding layer disposed at a lowermost portion of the non-emission area NEA and a metal layer disposed on the same layer as the first gate electrode 121 to the source electrode 122 through the contact hole.

In summary, the first capacitor electrode 151 of the storage capacitor 150 is a conductive area of the second active layer 134 in which the semiconductor layer and the transparent oxide layer are laminated on each other. The first capacitor electrode 151 can be electrically connected to the first gate electrode 121 of the first transistor 120 and the second source electrode 132 of the second transistor 130 through the contact hole. In the second capacitor electrode 152, a light shielding layer and a metal layer disposed on the same layer as the first gate electrode 121 can be electrically connected to the first source electrode 122 of the first transistor 120 and the third source electrode 142 of the third transistor 140 through the contact hole.

Next, the passivation layer 113 can be disposed on the first transistor 120, the second transistor 130, the third transistor 140, the storage capacitor 150, the high potential power line VDDL, the plurality of data lines DL, the plurality of reference lines RL, and the gate line GL. The passivation layer 113 is an insulating layer for protecting components below the passivation layer 113. For example, the passivation layer 113 can be configured by a single layer or a double layer of silicon oxide SiOx or silicon nitride SiNx, but is not limited thereto. Further, the passivation layer 113 can be omitted depending on the embodiment.

The planarization layer 114 can be disposed on the passivation layer 113 and the color filter. The planarization layer 114 is an insulating layer which planarizes an upper portion of the substrate 110 on which the first transistor 120, the second transistor 130, the third transistor 140, the storage capacitor 150, the high potential power line VDDL, the plurality of data lines DL, the plurality of reference lines RL, and the gate line GL are disposed. The planarization layer 114 can be formed of an organic material, and for example, can be configured by a single layer or a double layer of polyimide or photo acryl, but is not limited thereto.

The light emitting diode 160 is disposed in each of the plurality of sub pixels SP. The light emitting diode 160 is disposed on the planarization layer 114 in each of the plurality of sub pixels SP. The light emitting diode 160 includes an anode 115, an emission layer 117, and a cathode.

In the meantime, when the display device 100 according to the example embodiment of the present disclosure is a top emission type, a reflective layer which is formed of metal material having an excellent reflection efficiency, such as aluminum (Al) or silver (Ag) can be added below the anode 115. Therefore, the light emitted from the emission layer 117 is reflected to the anode 115 to be upwardly directed, that is, to be directed to the cathode. In contrast, when the display device 100 is a bottom emission type, the anode 115 can be formed of only a transparent conductive material. Further, the anode 115 is provided in the entire emission area EA and integrally extends to the non-emission area NEA. The anode 115 disposed in the non-emission area NEA is connected to the first source electrode 122 of the first transistor 120 to be applied with an electric signal.

In the emission area EA and the non-emission area NEA, the emission layer 117 is disposed on the anode 115. The emission layer 117 can be formed as one layer over the plurality of sub pixels SP. That is, the emission layers 117 of the plurality of sub pixels SP are connected to each other to be integrally formed. The emission layer 117 can be configured by one emission layer or can have a structure in which a plurality of emission layers which emits different color light is laminated. The emission layer 117 can further include an organic layer, such as a hole injection layer, a hole transport layer, an electron transport layer, and an electron injection layer.

In the emission area EA and the non-emission area NEA, the cathode is disposed on the emission layer 117. The cathode supplies electrons to the emission layer 117 so that the cathode can be formed of a conductive material having a low work function. The cathode can be formed as one layer over the plurality of sub pixels SP. That is, the cathode of each of the plurality of sub pixels SP is connected to be integrally formed. For example, the cathode can be formed of a transparent conductive material, such as indium tin oxide (ITO) and indium zinc oxide (IZO) or ytterbium (Yb) alloy and can further include a metal doping layer, but is not limited thereto. Also, the cathode of the light emitting diode 160 can be electrically connected to the low potential power line to be supplied with a low potential power signal.

Next, the gate line GL, the reference branch line RBL, and the data branch line DBL will be described with reference to FIGS. 3 to 5B.

First, the gate line GL disposed in the non-emission area NEA transmits a gate signal to each of the plurality of sub pixels SP and extends in a row direction to traverse the plurality of sub pixels SP. The gate line GL is sequentially supplied with a scan signal according to the control of the timing controller so that the gate line GL can be referred to as a scan line. As illustrated in FIG. 3, even though in the present disclosure, one scan line structure in which the second transistor 130 and the third transistor 140 operate for one gate line GL will be mainly described, two scan lines having two gate lines GL can also be applied in the same way.

Specifically, the gate line GL can be configured with a gate redundancy structure that is disposed in an area which intersects a plurality of signal lines (e.g., in the area over VDDL, DL or RL, etc.). The gate redundancy structure is a structure in which the gate line GL is branched into two lines (e.g., GBL1, GBL2) only in an area in which the gate line GL and the plurality of signal lines intersect (e.g., where GL overlaps with VDDL, DL or RL, etc.). The gate redundancy structure can include a first bridge line GBL1 which extends along the gate line GL and then is downwardly branched with respect to the Y-axis direction and a second bridge line GBL2 which is upwardly branched. For example, the gate line GL can fork into the first bridge line GBL1 and second bridge line GBL2, and then the first bridge line GBL1 and second bridge line GBL2 can converge and connect with each other back into the gate line GL.

Further, the non-emission area NEA can include signal lines which extend in the Y-axis direction while intersecting the gate line GL. The signal line which intersecting the gate line GL can be the high potential power line VDDL, the plurality of data lines DL, and the plurality of reference line RL as described above.

However, signal lines need to transmit the signal to each of the plurality of sub pixels SP so that a branch line BL extending from each signal line is used. The branch line BL can include a first high potential power branch line VDDBL1 and a second high potential power branch line VDDBL2 extending from the high potential power line VDDL, a data branch line DBL extending from the data line DL, and a reference branch line RBL extending from the reference line RL. The first high potential power branch line VDDBL1 and the second high potential power branch line VDDBL2 are connected to the high potential power line VDDL to apply the high potential voltage to the plurality of sub pixels SP. The data branch line DBL is connected to the plurality of data lines DL to apply a data voltage to the plurality of sub pixels SP and the reference branch line RBL is connected to the plurality of reference lines RL to apply the reference voltage Vref to the plurality of sub pixels SP.

The branch line BL can be formed integrally from the signal line which is electrically connected. In this situation, the branch line is formed of the same material on the same layer as the signal line so that the branch line BL can be configured by a conductive material, such as copper (Cu), aluminum (Al), molybdenum (Mo), nickel (Ni), titanium (Ti), chrome (Cr), or an alloy thereof, but it is not limited thereto.

However, the branch line BL can be formed on a layer different from the signal line and can be electrically connected through the contact hole. Specifically, as illustrated in FIG. 3, the branch line BL can be an area in which a part of the first active layer 124, the second active layer 134, and the third active layer 144 becomes conductive.

That is, at least a partial area of the branch line BL can include a lamination structure in which the semiconductor layer and the transparent oxide layer are laminated on each other. The branch line BL can be solely formed with the conductive semiconductor layer in at least a part and in the other part, can be formed with a lamination structure in which a semiconductor layer and a transparent oxide layer formed on the semiconductor layer are laminated. At this time, the transparent oxide layer can be configured by a transparent conductive material, such as tin oxide (TO), indium tin oxide (ITO), indium zinc oxide (IZO), or indium tin zinc oxide (ITZO), but is not limited thereto.

Specifically, the reference line RL is disposed at a left side of the blue sub pixel SPB and at a right side of the white sub pixel SPW, respectively, so that among the branch lines BL, the reference branch line RBL can be disposed in an area extending in the X-axis direction to transmit the reference voltage to each sub pixel SP.

Specifically, the reference branch line RBL extends in the X-axis direction to be connected to the green sub pixel SPG and the red sub pixel SPR and then is bent to the Y-axis direction in each pixel to be disposed in an L-shape (e.g., reference branch line RBL can include a 90 degree bend). Therefore, when the reference branch line RBL is configured by an opaque material, the reference branch line should be disposed in the non-emission area NEA and an area of the non-emission area NEA in the pixel may become larger, which may reduce the amount of real estate available for the emission area EA. However, in the display device 100 according to the example embodiment of the present disclosure, the branch line BL can include a laminated structure in which the semiconductor layer and the transparent oxide layer disposed on the semiconductor layer are laminated. Therefore, the reference branch line RBL can be disposed to pass over the emission area EA. In this way, the non-emission area NEA does not need to be made larger, and the size of the emission area EA can be maintained or made larger.

However, defects can occur during the manufacturing process of the display device 100, and when a specific line is open or disconnected during the process of producing the display device 100 causing a defective pixel, a repair process is needed for the pixel. For example, such a defective pixel may get stuck in an always on state, which can impair image quality (e.g., especially when displaying dark images or black). The repair process can be performed by cutting the line of the defective pixel to be dark or turning the pixel into a dead pixel that is always black. Specifically, the repair process can include a step of irradiating a laser beam onto the high potential power branch line VDDBL, the data branch line DBL, and the reference branch line RBL which transmit the high potential voltage, the data voltage, and the reference voltage to each of the plurality of sub pixels SP. When the laser is irradiated in a repair area of a wiring line including an opaque material, the laser is not transmitted through the repair area, but the laser energy is absorbed, received or reflected, in order to disconnect the corresponding wiring line. However, as in the display device 100 according to the example embodiment of the present disclosure, when the wiring line is formed of a transparent material, a laser in a specific wavelength band used for the repair process is not properly absorbed and the laser in a specific wavelength band is passing through the area so that the repair process cannot be carried out.

Therefore, in a partial area of the reference branch line RBL and the data branch line DBL, a repair unit 170 which overlaps the reference branch line RBL and the data branch line DBL is disposed. In other words, the reference branch line RBL and the data branch line DBL are made of transparent material so that they can be overlapped with the emission area EA in order to save space, but a small portion of each of reference branch line RBL and the data branch line DBL should have a type of structure that can properly absorb laser light so that the corresponding line can be cut, if needed, in order to properly carry out a repair process.

The repair unit 170 (e.g., a repair structure 170 or repair part 170) is for a repair process of the reference branch line RBL and the data branch line DBL and includes a first repair unit 171 (e.g., a first repair part 171) and a second repair unit 172 (e.g., a second repair part 172). The repair unit 170 can be disposed on the same layer as the light shielding layer disposed in the non-emission area NEA. For example, the repair unit 170 is disposed on the same layer as the light shielding layer disposed between the substrate 110 and the buffer layer 111 in the non-emission area NEA and overlaps with the reference branch line RBL and the data branch line DBL disposed above the repair unit 170. Therefore, the repair unit 170 is disposed on a layer adjacent to the reference branch line RBL and the data branch line DBL on which the repair process will be performed to more easily perform the repair process.

Further, referring to FIG. 4, the repair unit 170 has a Y shape and can include two protrusions that overlap with portions of the reference branch line RBL and the data branch line DBL, respectively. In other words, a portion of the light shielding layer LS that is under storage capacitor 150 can extend out to form a “Y” shaped protrusion that includes two tab portions that respectively overlap with a portion of the reference branch line RBL and a portion of the data branch line DBL (e.g., see FIG. 6A and FIGS. 3 and 4). The first repair unit 171 is disposed to overlap with a portion of the reference branch line RBL and a portion of the data branch line DBL and the second repair unit 172 extends from the light shielding layer to be connected to the first repair unit 171. For example, the second repair unit 172 can form the “base” or lower part of the “Y” shape, and the first repair unit 171 can form the “two prongs” of the upper part of the “Y” shape. Of course, embodiments are not limited thereto, and the repair unit 170 can have other similar shapes, such as a “T” shape, a “V” shape, a solid shape or a paddle shape. Specifically, the second repair unit 172 of the repair unit 170 extends from the light shielding layer and is divided into two parts after passing the gate line GL. In the divided parts of the repair unit 170, the first repair unit 171 is disposed to overlap with a portion of the reference branch line RBL and a portion of the data branch line DBL. Specifically, the width of the first repair unit 171 can be smaller than the widths of the reference branch line RBL and the data branch line DBL in a portion overlapping the first repair unit 171. Therefore, the repair unit 170 has a Y shape and the first repair unit 171 has a width smaller than the widths of the reference branch line RBL and the data branch line DBL and extends from the light shield layer so that a parasitic capacitance with the wiring line disposed on the other layer can be minimized. In order words, the area of the repair unit 170 is kept small so that it does not cause undesirable parasitic capacitance and does not interference with the other signal lines.

In the meantime, when the repair unit 170 has a T shape, an interval between the areas of the reference branch line RBL and the data branch line DBL to be repaired is small. Accordingly, during the patterning, there are problems in that the first repair unit 171 disposed to overlap with the reference branch line RBL and the data branch line DBL is crumpled or a line width to be disconnected during the repair is increased. Therefore, when the repair unit 170 has a Y shape, an interval between the areas of the reference branch line RBL and the data branch line DBL to be repaired is ensured. Accordingly, during the patterning, problems with the first repair unit 171 disposed to overlap with the reference branch line RBL and the data branch line DBL, respectively, becoming crumpled or a line width to be disconnected during the repair is increased can be suppressed or prevented.

The first repair unit 171 of the repair unit 170 is desirably disposed to be spaced apart from the gate line GL with an interval of at least 4 μm or more. This is because if the first repair unit 171 overlaps with the gate line GL, the second transistor 130 and the third transistor 140 which need to be turned off during the driving of the display device 100 can become undesirably turned on and cause a driving failure problem. Therefore, the first repair unit 171 is spaced apart from the gate line GL by 4 μm or more so that the driving failure problem caused by the second transistor 130 and the third transistor 140 which are turned off during the driving of the display device 100 can be suppressed or prevented.

The repair unit 170 extends from the light shielding layer so that it can be configured by copper (Cu), aluminum (Al), molybdenum (Mo), nickel (Ni), titanium (Ti), chrome (Cr), or an alloy thereof, that is, an opaque metal. Therefore, the laser in a specific wavelength band is accepted or reflected in an area overlapping the reference branch line RBL and the data branch line DBL so that the repair unit 170 performs the repair process in the corresponding area.

However, the repair unit 170 disposed in each of the blue sub pixel SPB, the green sub pixel SPG, the red sub pixel SPR, and the white sub pixel SPW can be disposed in an area excluding an area adjacent to the signal line. The repair unit 170 in an area which is disposed to be close to the signal line can be omitted. Specifically, the repair unit 170 can be omitted in an area adjacent to a wiring line to which a constant voltage is always applied. For example, the first repair unit 171 of the repair unit 170 is not disposed in an area overlapping the reference branch line RBL of the blue sub pixel SPB which is adjacent to the first reference line RL1 so that a potential short-circuit generated between the reference branch line RBL and the repair unit 170 can be suppressed or prevented. At this time, the repair process for the reference branch line RBL of the blue sub pixel SPB disposed in an area adjacent to the first reference line RL1 can perform the repair process in an area overlapping the first reference line RL1.

FIG. 5A illustrates a structure in which the first repair unit 171 of the repair unit 170 and the data branch line DBL overlap with each other before performing the repair process, and FIG. 5B illustrates a structure after performing the repair process. Referring to FIG. 5B, after performing the repair process by laser, in an area of the data branch line DBL having a structure in which the semiconductor layer DBL1 and the transparent oxide layer DBL2 are laminated, overlapping the first repair unit 171 of the repair unit 170, the data branch line DBL can be disconnected together with the first repair unit 171. That is, when the laser is irradiated in the area overlapping with the first repair unit 171 and the data branch line DBL, the first repair unit 171 receives and reflects the energy of the laser so that the semiconductor layer DBL1 and the transparent oxide layer DBL2 of the data branch line DBL can be also disconnected and cut. Therefore, the current path through which the reference voltage is transmitted to the sub pixel is disconnected so that the sub pixel can become dark and stay black by performing the laser repair process. However, in FIGS. 5A and 5B, it is illustrated that the data branch line DBL in the area overlapping the first repair unit 171 of the repair unit 170 has a laminated structure in which the semiconductor layer DBL1 and the transparent oxide layer DBL2 are laminated. But it is not limited thereto and the data branch line DBL can have a single layer structure only formed by the semiconductor layer DBL1.

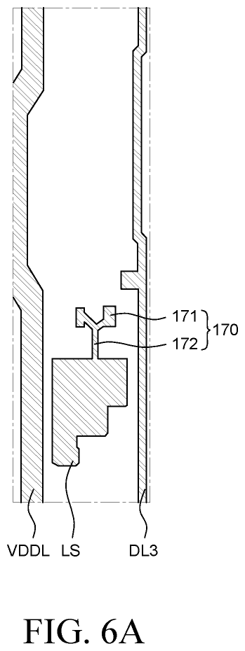

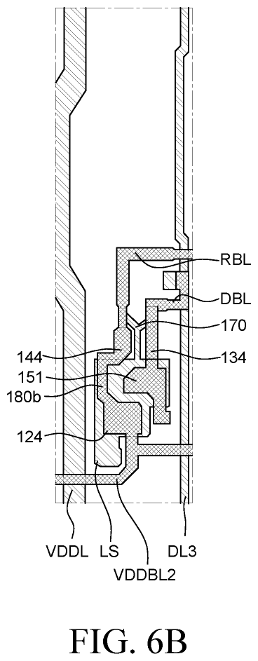

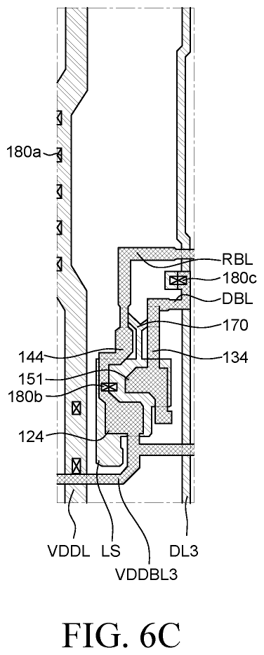

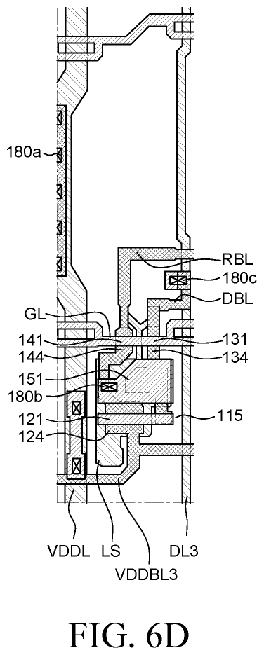

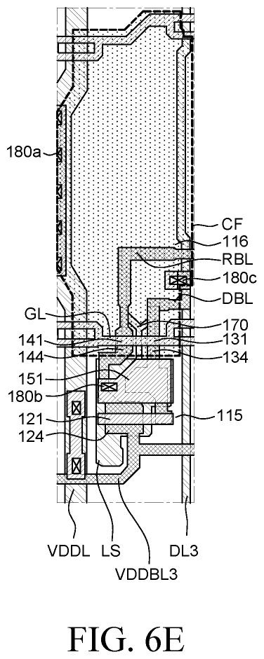

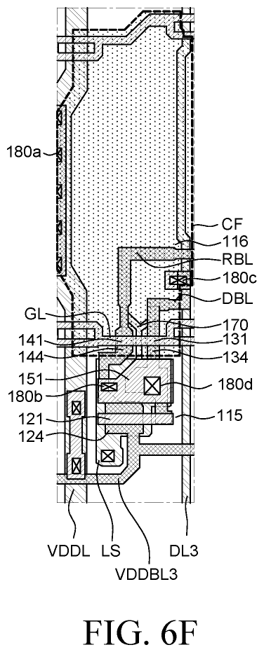

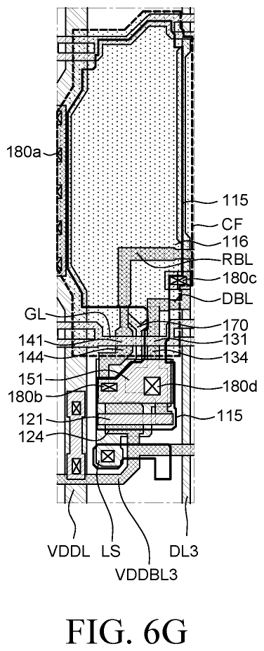

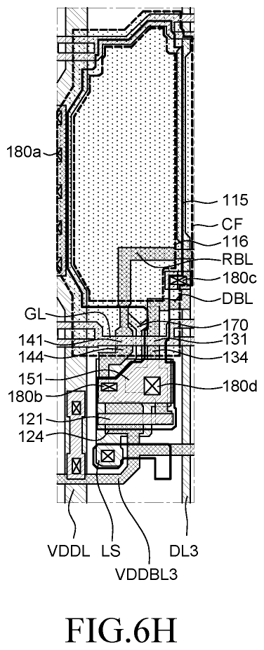

FIGS. 6A to 6H are plan views sequentially illustrating a manufacturing process of a display device according to an example embodiment of the present disclosure.

First, referring to FIG. 6A, the high potential power line VDDL, the data line DL, the light shielding layer LS, and the repair unit 170 can be formed on the substrate 110 and the buffer layer 111 can be formed on the substrate 110 on which the high potential powerline VDDL, the data line DL, the light shielding layer LS, and the repair unit 170 are formed.

At this time, the high potential powerline VDDL, the data line DL, the light shielding layer LS, and the repair unit 170 can be formed by forming a metal layer on the substrate 110 and then selectively patterning the metal layer by the mask process. For example, the high potential powerline VDDL, the data line DL, the light shielding layer LS, and the repair unit 170 can be formed of a same material, on a same layer and during the same processing step.

Thereafter, the buffer layer 111 can be disposed on the substrate 110 to cover the high potential powerline VDDL, the data line DL, the light shielding layer LS, and the repair unit 170.

Next, referring to FIG. 6B, an active layer can be formed on the substrate 110.

At this time, the first active layer 124, the second active layer 134, the third active layer 144, the reference branch line RBL, the data branch line DBL, and the high potential power branch line VDDBL2 can be formed on the substrate 110 by patterning using the mask process.

Specifically, after sequentially depositing the semiconductor layer material and the transparent oxide layer material, the transparent oxide layer is removed from the channel region of the area of the first active layer 124, the second active layer 134, and the third active layer 144 to form the channel region of the first active layer 124, the second active layer 134, and the third active layer 144. At this time, in a partial area of the area overlapping the light shielding layer LS from which the transparent oxide layer is not removed, a first capacitor electrode 151 can be formed.

Next, referring to FIG. 6C, a first contact hole 180a, a second contact hole 180b, and a third contact hole 180c can be formed.

At this time, the first contact hole 180a, the second contact hole 180b, and the third contact hole 180c which expose a part of the high potential powerline VDDL, the data line DL, and the light shielding layer LS can be formed by patterning using the mask process.

Next, referring to FIG. 6D, the gate insulating layer 112 and the gate layer can be sequentially formed on the substrate 110.

At this time, the gate insulating layer 112 can be formed of a single layer of silicon nitride SiNx or silicon oxide SiOx which is an inorganic material or a multiple layer of silicon nitride SiNx or silicon oxide SiOx.

Thereafter, the gate line GL, the first gate electrode 121, the second gate electrode 131, the third gate electrode 141, and the second capacitor electrode 152 can be formed on the substrate 110 by pattering using the mask process.

Next, referring to FIG. 6E, a passivation layer 113 and a color filter CF can be sequentially formed on the substrate 110.

At this time, the color filter CF corresponding to the pixel can be formed only in the emission area EA on the substrate 110.

Next, referring to FIG. 6F, after forming the planarization layer 114 on the substrate 110, the fourth contact hole 180d can be formed.

A planarization layer 114 can be formed, which planarizes an upper portion of the substrate 110 in which the passivation layer 113 and the color filter CF are formed. At this time, the planarization layer 114 can be formed of an organic material, and for example, can be configured by a single layer or a double layer of polyimide or photo acryl, but is not limited thereto.

Next, a fourth contact hole 180d which partially removes a part of the passivation layer 113 and a part of the planarization layer 114 can be formed.

Next, referring to FIG. 6G, the anode 115 can be formed on the planarization layer 114.

At this time, the anode 115 can be formed on the planarization layer 114 and can be electrically connected to the first source electrode 122 of the first transistor 120 through the fourth contact hole 180d formed in the passivation layer 113 and the planarization layer 114. The anode 115 supplies holes to the emission layer to be formed by a conductive material having a high work function and for example, can be formed of a transparent conductive material such as indium tin oxide (ITO) and indium zinc oxide (IZO), but is not limited thereto.

Next, referring to FIG. 6H, the bank 116 can be formed on the anode 115 and the planarization layer 114.

At this time, the bank 116 can cover a part of the anode 115 and a part of the wiring line. The bank 116 can be formed to divide the emission area EA. The bank 116 can be formed of an organic insulating material. For example, the bank 116 can be formed of polyimide, acryl, or benzocyclobutene (BCB) resin, but the present disclosure is not limited thereto.

In the meantime, the branch line extending from the plurality of signal lines is integrally formed with the active layer and a partial area of the active layer becomes conductive to transmit the signal to each sub pixel. However, in order to conductize the partial area of the active layer, for example, the branch line includes a laminated structure in which the semiconductor layer and an auxiliary metal layer disposed on the semiconductor layer are laminated. As described above, in the structure in which the semiconductor layer and the auxiliary metal layer are laminated, during the repair process of the branch line, the auxiliary metal layer receives or reflects laser in a specific wavelength band so that the corresponding wiring line can be disconnected. Therefore, there it is difficult to perform the repair process of the signal line due to the specific configuration of the repair unit 170.

However, in order to minimize the area of the non-emission area, attempts have been made to configure the branch line with transparent materials. For example, like the display device 100 according to the example embodiment of the present disclosure, the branch line can be disposed with a semiconductor layer and a transparent oxide layer disposed on the semiconductor layer. The transparent oxide layer is formed of a transparent conductive material such as indium zinc oxide (IZO) so that when the transparent oxide layer is included to conductize the branch line, the entire area of the branch line has a transparency. Therefore, even though the branch line passes through the emission area, the aperture ratio is not affected. However, the branch line including the transparent oxide layer transmits the laser to perform the repair process on the signal line as it is, the additional metal layer structure is necessary. Therefore, the display device has used a structure in which the additional metal layer formed of the same material on the same layer as the gate metal layer is disposed in a partial area of the branch line. However, this structure has problems in that a contact which electrically connects the additional metal layer and the branch line is included and the distance from the surrounding pattern needs to be considered so that the opening area is reduced.

Therefore, in the display device 100 according to the example embodiment of the present disclosure, in order to perform the repair process, the repair unit 170 is disposed to overlap with the reference branch line RBL and the data branch line DBL to stably perform the repair process while ensuring the aperture ratio.

That is, the branch line includes a laminated structure in which the semiconductor layer and the transparent oxide layer laminated on the semiconductor layer are laminated so that even though the branch line passes through the emission area EA, it does not affect the aperture ratio since it is transparent. Therefore, the branch line does not need to be disposed only in the non-emission area, so that the design can be freely performed and the large aperture ratio can be ensured.

Further, as described above, the branch line is configured by the transparent material so that the opening area which is reduced by the additional metal layer on the branch line required to perform the repair process can be ensured. That is, the display device 100 according to the example embodiment of the present disclosure can maximize the aperture ratio and implement a stable repair process for the reference line RL.

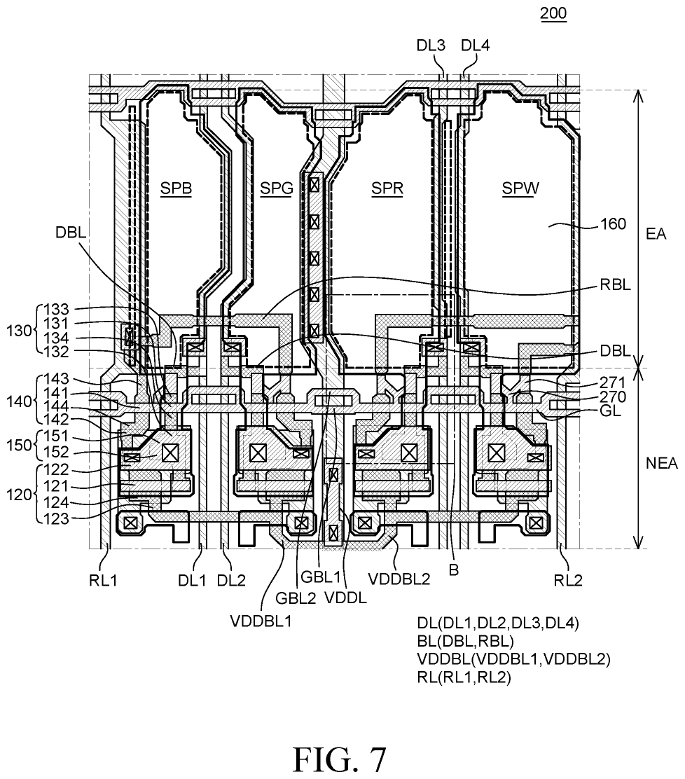

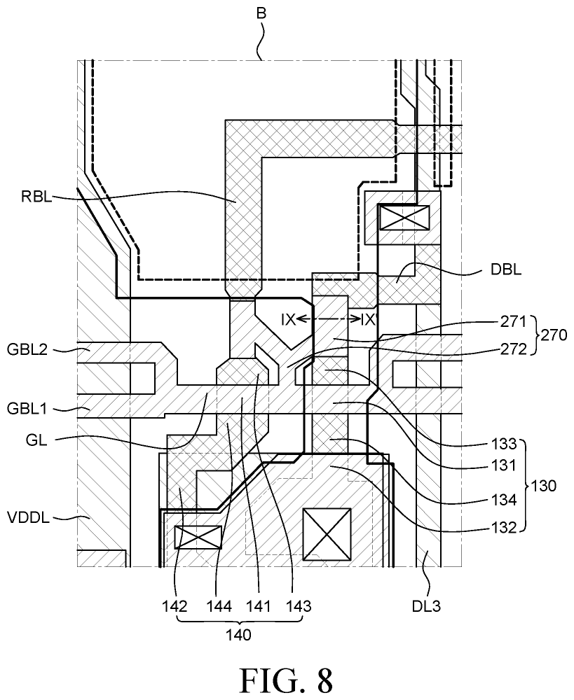

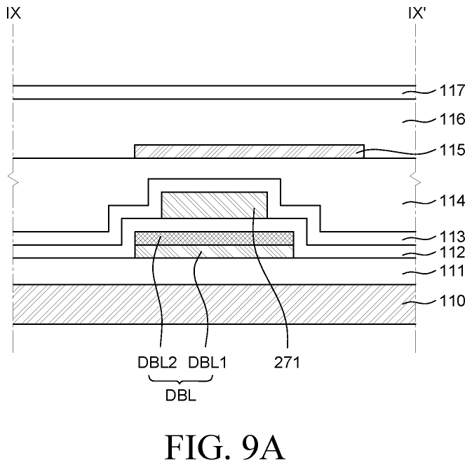

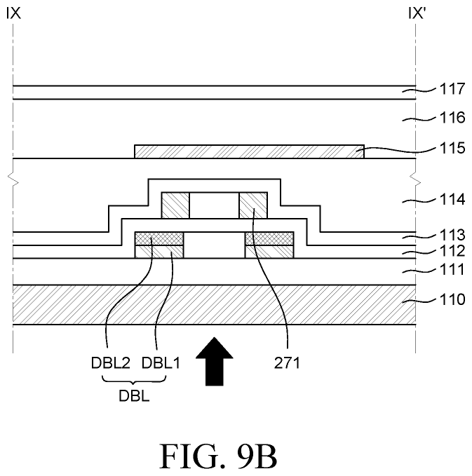

FIG. 7 is an enlarged plan view of a display device according to another example embodiment of the present disclosure. FIG. 8 is an enlarged view of an area A of FIG. 7. FIGS. 9A and 9B are cross-sectional views taken along the line IX-IX′ of FIG. 8. Configurations of the display device 200 of FIGS. 7 to 9B are substantially the same except for the repair unit 270 so that the redundant description will be omitted. For example, the embodiment in FIG. 7 is similar to the embodiment in FIG. 4, except that instead of having the repair unit being a portion that extends or protrudes out of the light shielding layer overlapping with the capacitor 150, in FIG. 7 the repair unit 270 extends or protrudes out the gate line GL in order to overlap with portions of the wiring lines to be cut. In FIG. 8, for the convenience of description, only the third transistor 140, the data line DL3, the gate line GL, the high potential power line VDDL, the data branch line DBL, the reference branch line RBL, and the repair unit 270 are illustrated. In FIGS. 9A and 9B, only a configuration from the substrate 110 to the emission layer 117, among various components of the display device 200 is illustrated for the convenience of description. FIGS. 9A and 9B are cross-sectional views of a red sub pixel SPR, but a cross-sectional structure of the red sub pixel SPR can be substantially the same as the cross-sectional structure of a white sub pixel SPW, a blue sub pixel SPB and a green sub pixel SPG.

Referring to FIGS. 7 and 8, in a partial area of the reference branch line RBL and the data branch line DBL, a repair unit 270 is disposed which overlaps with the reference branch line RBL and the data branch line DBL.

The repair unit 270 is for a repair process of the reference branch line RBL and the data branch line DBL and includes a first repair unit 271 and a second repair unit 272.

The repair unit 270 is disposed on the same layer as the gate line GL disposed in the non-emission area NEA to overlap the reference branch line RBL and the data branch line DBL. For example, the repair unit 270 is disposed on the same layer as the gate line GL disposed on the gate insulating layer 112 in the non-emission area NEA and overlaps the reference branch line RBL and the data branch line DBL disposed below the repair unit 270. Therefore, the repair unit 270 is disposed on a layer adjacent to the reference branch line RBL and the data branch line DBL on which the repair process will be performed to more easily perform the repair process.

Further, referring to FIG. 8, the repair unit 270 (e.g., repair part 270) has a Y shape. The first repair unit 271 (e.g., first repair part 271) is disposed to overlap with a portion of the reference branch line RBL and a portion of the data branch line DBL, and the second repair unit 272 (e.g., second repair part 272) extends from the gate line GL to be connected to the first repair unit 271. For example, the second repair part 272 can form the base of the “Y” shape which extends out of the gate line LG, and the first repair part 271 can form the two prongs of the upper part of the “Y” shape. However, embodiments are not limited thereto, and other shapes can be used for the repair part 270, such as a “T” shape, a “V” shape, a solid shape or a paddle shape. Although, the “Y” shape can have certain advantages, as discussed above. Specifically, the second repair unit 272 of the repair unit 270 extends from the gate line GL and can be divided into two parts. In the divided parts of the second repair unit 272, the first repair unit 271 can be disposed to overlap with the reference branch line RBL and the data branch line DBL, respectively. Specifically, the width of the first repair unit 271 can be smaller than the widths of the reference branch line RBL and the data branch line DBL in a portion overlapping the first repair unit 271. Therefore, the repair unit 270 has a Y shape and the first repair unit 271 has a width smaller than the widths of the reference branch line RBL and the data branch line DBL and extends from the gate line GL so that a parasitic capacitance with the wiring line disposed on the other layer can be minimized.

In the meantime, when the repair unit 270 has a T shape, an interval between the areas of the reference branch line RBL and the data branch line DBL to be repaired is small. Accordingly, during the patterning, there are problems in that the first repair unit 271 disposed to overlap with the reference branch line RBL and the data branch line DBL can become crumpled or a line width to be disconnected during the repair is increased. Therefore, when the repair unit 270 according to another example embodiment of the present disclosure has a Y shape, an interval between the areas of the reference branch line RBL and the data branch line DBL to be repaired is ensured. Accordingly, during the patterning, problems in that the first repair unit 271 disposed to overlap with the reference branch line RBL and the data branch line DBL, respectively, becomes crumpled or a line width to be disconnected during the repair is increased can be suppressed or prevented.

The first repair unit 271 of the repair unit 270 is desirably disposed to be spaced apart from the gate line GL with an interval of at least 4 μm or more. This is because if the first repair unit 271 near or adjacent to the gate line GL, the second transistor 130 and the third transistor 140 which need to be turned off during the driving of the display device 200 are turned on to cause the driving failure problem. Therefore, the first repair unit 271 is spaced apart from the gate line GL by 4 μm or more so that the driving failure problem caused by the second transistor 130 and the third transistor 140 which are turned off during the driving of the display device 200 can be suppressed or prevented.

The repair unit 270 extends from the gate line GL so that it can be configured by copper (Cu), aluminum (Al), molybdenum (Mo), nickel (Ni), titanium (Ti), chrome (Cr), or an alloy thereof, that is, an opaque metal. Therefore, the laser in a specific wavelength band can be properly accepted or reflected in an area overlapping the reference branch line RBL and the data branch line DBL so that the repair unit 270 can perform the repair process in the corresponding area.

However, the repair unit 270 disposed in each of the blue sub pixel SPB, the green sub pixel SPG, the red sub pixel SPR, and the white sub pixel SPW can be disposed in an area excluding an area overlapping with the signal line. That it, the repair unit 270 in an area which is disposed to be close to the signal line can be omitted. Specifically, the repair unit 270 can be omitted in an area adjacent to a wiring line to which a constant voltage is always applied. For example, the first repair unit 271 of the repair unit 270 is not disposed in an area overlapping the reference branch line RBL of the blue sub pixel SPB which is adjacent to the first reference line RL1 so that a potential short-circuit generated between the reference branch line RBL and the repair unit 270 can be suppressed or prevented.

The reference branch line RBL and the data branch line DBL can be formed with a laminated structure in which the semiconductor layer and the transparent oxide layer are laminated in an area overlapping with the first repair unit 271 of the repair unit 270. This is because when the area of the reference branch line RBL and the data branch line DBL overlapping with the first repair unit 271 is formed only by the semiconductor layer without having a transparent oxide layer, the area can operate as a transistor. Therefore, in the display device 200 of the present disclosure, the reference branch line RBL and the data branch line DBL in an area overlapping the first repair unit 271 are formed with a laminated structure in which the semiconductor layer and the transparent oxide layer are laminated so as not to operate as a transistor. By doing this, operation failure can be suppressed or prevented.

FIG. 9A illustrates a structure in which the first repair unit 271 of the repair unit 270 and the data branch line DBL overlap with each other before performing the repair process, and FIG. 9B illustrates a structure after performing the repair process. Referring to FIG. 9B, after performing the repair process by laser, in an area of the data branch line DBL having a structure in which the semiconductor layer DBL1 and the transparent oxide layer DBL2 are laminated, overlapping the first repair unit 271 of the repair unit 270, the data branch line DBL can be disconnected from each other because of laser light reflected off of the first repair unit 271. That is, when the laser is irradiated in the area overlapping the first repair unit 271 and the data branch line DBL, the first repair unit 271 receives and reflects the energy of the laser so that the semiconductor layer DBL1 and the transparent oxide layer DBL2 of the data branch line DBL can be also disconnected. Therefore, the current path through which the reference voltage is transmitted to the sub pixel is disconnected so that the sub pixel can become dark and remain in an off state by the laser repair process.

Therefore, in the display device 100 according to the example embodiment of the present disclosure, in order to perform the repair process, the repair unit 170 is disposed to overlap with portions of the reference branch line RBL and the data branch line DBL to stably perform the repair process while ensuring the aperture ratio.

That is, the branch line includes a laminated structure in which the semiconductor layer and the transparent oxide layer laminated on the semiconductor layer are laminated so that even though the branch line passes the emission area EA, it does not affect the aperture ratio. Therefore, the branch line does not need to be disposed only in the non-emission area, so that the design can be freely performed and the aperture ratio can be ensured as compared with the structure of the reference branch line of the related art.

Further, as described above, the branch line is configured by the transparent material so that the opening area which is reduced by the additional metal layer on the branch line required to perform the repair process can be ensured. That is, the display device 100 according to the example embodiment of the present disclosure can implement stable repair on the reference line RL while maximizing the aperture ratio.

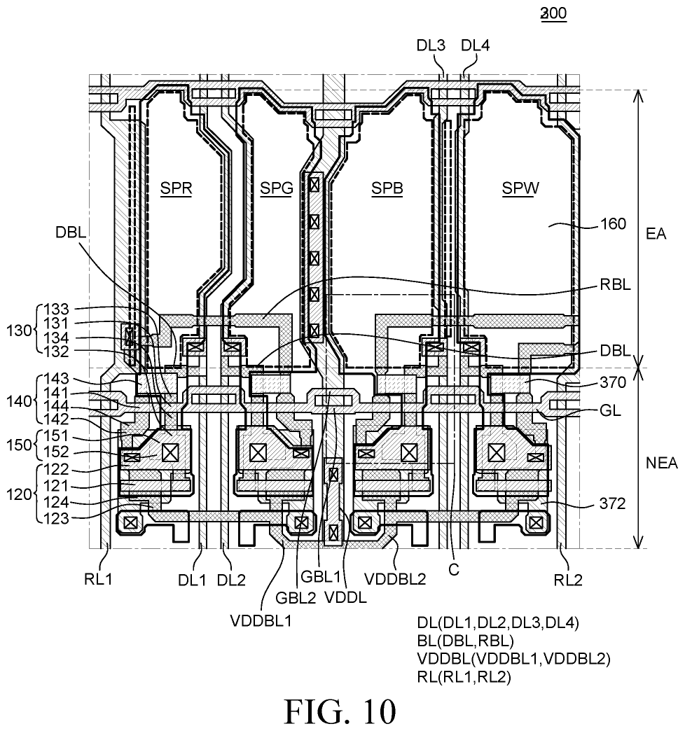

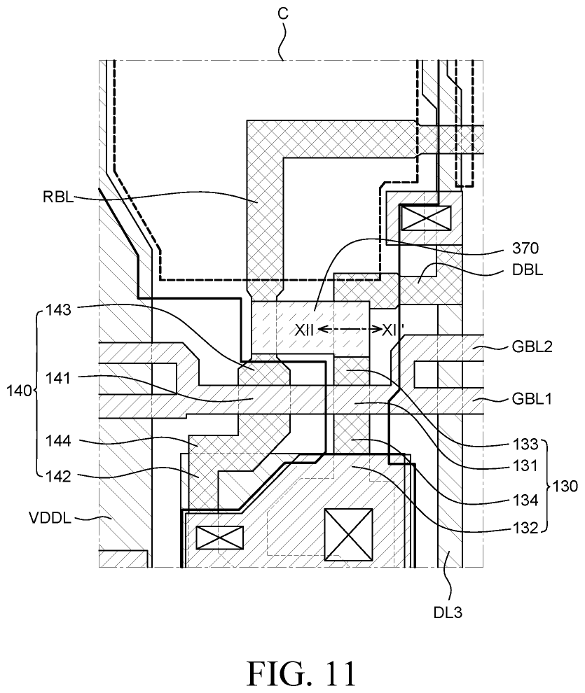

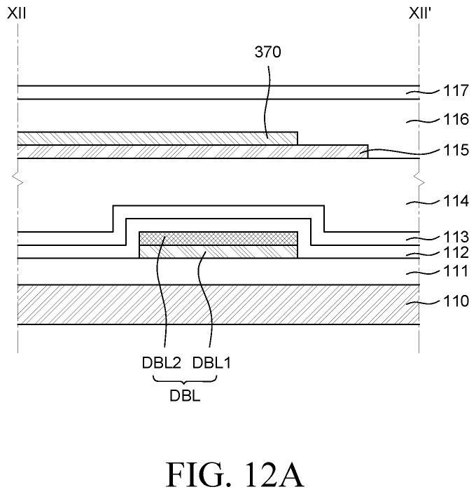

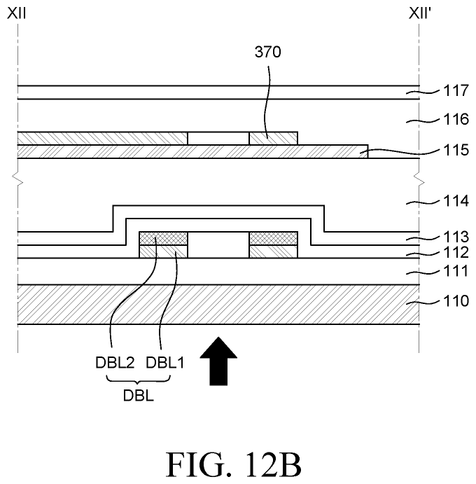

FIG. 10 is an enlarged plan view of a display device according to still another embodiment of the present disclosure. FIG. 11 is an enlarged view of an area C of FIG. 10; and FIGS. 12A and 12B are cross-sectional views taken along the line XII-XII′ of FIG. 11.

Configurations of the display device 300 of FIGS. 10 to 12B are substantially the same except for the repair unit 370 so that the redundant description will be omitted. For example, the repair unit 370 is disposed as an individual part that is spaced apart from the gate line GL and overlaps with portions of corresponding wiring lines to be cut. In FIG. 11, for the convenience of description, only the third transistor 140, the data line DL3, the gate line GL, the high potential power line VDDL, the data branch line DBL, the reference branch line RBL, and the repair unit 370 are illustrated. In FIGS. 12A and 12B, only a configuration from the substrate 110 to the emission layer 117, among various components of the display device 300 is illustrated for the convenience of description. FIGS. 12A and 12B are cross-sectional views of a red sub pixel SPR, but a cross-sectional structure of the red sub pixel SPR can be substantially the same as the cross-sectional structure of a white sub pixel SPW, a blue sub pixel SPB and a green sub pixel SPG.

Referring to FIGS. 10 and 11, in a partial area of the reference branch line RBL and the data branch line DBL, a repair unit 370 is disposed which overlaps with portions of the reference branch line RBL and the data branch line DBL.

The repair unit 370 is used for a repair process of the reference branch line RBL and the data branch line DBL. The repair unit 370 can be disposed on the anode 115 in the non-emission area. For example, the repair unit 370 can be disposed above the anode 115 disposed in the non-emission area NEA to be in direct contact therewith and overlap with the reference branch line RBL and the data branch line DBL disposed below the repair unit 370.

Further, referring to FIG. 11, the repair unit 370 can be disposed to overlap with the repair area of the reference branch line RBL and the data branch line DBL with a rectangular shape. Therefore, as compared with the repair unit which extends from the repair area to the gate line GL to be disposed between the second transistor 130 and the third transistor 140, it is easily applicable to a higher resolution model without being affected by the design margin such as a price between the second transistor 130 and the third transistor 140.

The repair unit 370 is desirably disposed to be spaced apart from the gate line GL with an interval of at least 4 μm or more. This is because if the repair unit 370 overlaps with the gate line GL, the second transistor 130 and the third transistor 140 which need to be turned off during the driving of the display device 200 may inadvertently get turned on to cause a driving failure problem. Therefore, the repair unit 370 is spaced apart from the gate line GL by 4 μm or more to suppress or prevent the driving failure problem caused by the second transistor 130 and the third transistor 140 which should be turned off during the driving.

In the meantime, the repair unit 370 can be configured by copper (Cu), aluminum (Al), molybdenum (Mo), nickel (Ni), titanium (Ti), chrome (Cr), or an alloy thereof, that is, an opaque metal. Therefore, the laser in a specific wavelength band is accepted or reflected in an area overlapping with the reference branch line RBL and the data branch line DBL so that the repair unit 370 can perform the repair process in the corresponding area.

FIG. 12A illustrates a structure in which the repair unit 370 and the data branch line DBL overlap with each other before performing the repair process, and FIG. 12B illustrates a structure after performing the repair process. Referring to FIG. 12B, after performing the repair process by laser, in an area of the data branch line DBL having a structure in which the semiconductor layer DBL1 and the transparent oxide layer DBL2 are laminated, overlapping the repair unit 370, the data branch line DBL can be disconnected by laser light reflected off of the repair unit 370. That is, when the laser is irradiated in the area overlapping the repair unit 370 and the data branch line DBL, the repair unit 370 receives and reflects the energy of the laser so that the semiconductor layer DBL1 and the transparent oxide layer DBL2 of the data branch line DBL can be also disconnected. Therefore, the current path through which the reference voltage is transmitted to the sub pixel is disconnected so that the sub pixel can become dark and remain in the off state by the laser repair process. However, in FIGS. 12A and 12B, it is illustrated that the data branch line DBL in the area overlapping with the repair unit 370 has a laminated structure in which the semiconductor layer DBL1 and the transparent oxide layer DBL2 are laminated. But it is not limited thereto and the data branch line DBL can have a single layer structure only formed by the semiconductor layer DBL1.

The example embodiments of the present disclosure can also be described as follows below.

According to an aspect of the present disclosure, there is provided a display device. The display device includes a plurality of sub pixels disposed on a substrate including an emission area and a non-emission area, a gate line disposed in the non-emission area, the gate line extending in a first direction, at least one signal line disposed in the non-emission area, the at least one signal line overlapping with the gate line, at least one branch line connected to the at least one signal line and a repair part overlapping with the at least one branch line, the repair part being spaced apart from the at least one branch line.

The repair part can be configured to reflect laser light onto a portion of the least one branch line overlapping with the repair part and cut the least one branch line to deactivate one of the plurality of sub pixels.

A portion of the at least one branch line can include a laminated structure in which a semiconductor layer and a transparent oxide layer.

The portion of the at least one branch having the laminated structure can be overlapped with the emission area.

The repair part can have a “Y” shape or the repair part includes a base portion that forks into two protruding portions.

The repair part can be overlapped with the at least one branch line, and the repair part can be disposed on a same layer as a light shielding layer disposed in the non-emission area.

The repair part can include a first repair part overlapping with the at least one branch line and a second repair part extending from the first repair part and connected to the light shielding layer.

A width of the first repair part can be smaller than a width of the at least one branch line.

The first repair part does not overlap with a signal line that applied with a constant voltage.

The repair part can be overlapped with the at least one branch line and can be disposed on a same layer as the gate line.

The repair part can include a first repair part overlapping with the at least one branch line and a second repair part extending from the first repair part and connected to the gate line.

A portion of the at least one branch line overlapping with the first repair part can include a laminated structure including a semiconductor layer and a transparent oxide layer.

The repair part can be disposed to overlap with the at least one branch line above an anode disposed in the non-emission area.

The at least one signal line can include at least one high potential power line disposed in the non-emission area, at least one data line disposed in the non-emission area and at least one reference line disposed in the non-emission area.

The gate line can include a branched portion including a first bridge line and a second bridge line, the branched portion of gate line overlapping with at least one of the at least one high potential power line, the at least one data line, and the at least one reference line.

The at least one branch line can include at least one reference branch line connected to the at least one reference line and configured to apply a reference voltage to the plurality of sub pixels and at least one data branch line connected to the at least one data line and configured to apply a data voltage to the plurality of sub pixels.

The at least one signal line can extend in a second direction intersecting with the first direction.

According to another aspect of the present disclosure, there is provided a display device. The display device includes a plurality of sub pixels disposed on a substrate including an emission area and a non-emission area, a gate line disposed in the non-emission area, the gate line extending in a first direction, a first signal line overlapping with the gate line, the first signal line extending in a second direction, a first branch line disposed in the emission area and connected to the first signal line, a second signal line overlapping with the gate line, the second signal line extending in the second direction, a second branch line disposed in the emission area and connected to the second signal line, a repair part disposed between the first branch line and the second branch line and an insulating layer disposed between the repair part and the first and second branch lines, wherein a first portion of the repair part overlaps with a portion of the first branch line and a second portion of the repair part overlaps with a portion of the second branch line.

The first branch line and the second branch line can include a transparent material. The first portion of the repair part can include a reflective material and is configured to reflect laser light onto the portion of the first branch line and wherein the second portion of the repair part includes the reflective material and is configured to reflect the laser light onto the portion of the second branch line.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a plurality of sub pixels disposed on a substrate including an emission area and a non-emission area;
a gate line disposed in the non-emission area, the gate line extending in a first direction;
at least one signal line disposed in the non-emission area, the at least one signal line overlapping with the gate line;
at least one branch line connected to the at least one signal line; and
a repair part overlapping with the at least one branch line, the repair part being spaced apart from the at least one branch line.

2. The display device according to claim 1, wherein the repair part is configured to reflect laser light onto a portion of the least one branch line overlapping with the repair part and cut the least one branch line to deactivate one of the plurality of sub pixels.

3. The display device according to claim 1, wherein a portion of the at least one branch line includes a laminated structure including a semiconductor layer and a transparent oxide layer.

4. The display device according to claim 3, wherein the portion of the at least one branch having the laminated structure overlaps with the emission area.

5. The display device according to claim 1, wherein the repair part has a “Y” shape or the repair part includes a base portion that forks into two protruding portions.

6. The display device according to claim 5, wherein the repair part overlaps with the at least one branch line, and the repair part is disposed on a same layer as a light shielding layer disposed in the non-emission area.

7. The display device according to claim 6, wherein the repair part includes:
a first repair part overlapping with the at least one branch line; and
a second repair part extending from the first repair unit and connected to the light shielding layer.

8. The display device according to claim 7, wherein a width of the first repair part is smaller than a width of the at least one branch line.

9. The display device according to claim 8, wherein the first repair part does not overlap with a signal line that applied with a constant voltage.

10. The display device according to claim 5, wherein the repair part overlaps with the at least one branch line and is disposed on a same layer as the gate line.

11. The display device according to claim 10, wherein the repair part includes:
a first repair part overlapping with the at least one branch line; and
a second repair part extending from the first repair part and connected to the gate line.

12. The display device according to claim 11, wherein a portion of the at least one branch line overlapping with the first repair part includes a laminated structure including a semiconductor layer and a transparent oxide layer.

13. The display device according to claim 1, wherein the repair part is disposed to overlap with the at least one branch line above an anode disposed in the non-emission area.

14. The display device according to claim 1, wherein the at least one signal line includes:
at least one high potential power line disposed in the non-emission area;
at least one data line disposed in the non-emission area; and
at least one reference line disposed in the non-emission area.

15. The display device according to claim 14, wherein the gate line includes a branched portion including a first bridge line and a second bridge line, the branched portion of gate line overlapping with at least one of the at least one high potential power line, the at least one data line, and the at least one reference line.

16. The display device according to claim 14, wherein the at least one branch line includes:
at least one reference branch line connected to the at least one reference line and configured to apply a reference voltage to the plurality of sub pixels; and
at least one data branch line connected to the at least one data line and configured to apply a data voltage to the plurality of sub pixels.

17. The display device according to claim 14, wherein the at least one signal line extends in a second direction intersecting with the first direction.

18. A display device, comprising:
a plurality of sub pixels disposed on a substrate including an emission area and a non-emission area;
a gate line disposed in the non-emission area, the gate line extending in a first direction;
a first signal line overlapping with the gate line, the first signal line extending in a second direction;
a first branch line disposed in the emission area and connected to the first signal line;
a second signal line overlapping with the gate line, the second signal line extending in the second direction;
a second branch line disposed in the emission area and connected to the second signal line;
a repair part disposed between the first branch line and the second branch line; and
an insulating layer disposed between the repair part and the first and second branch lines,
wherein a first portion of the repair part overlaps with a portion of the first branch line and a second portion of the repair part overlaps with a portion of the second branch line.

19. The display device according to claim 18, wherein the first branch line and the second branch line include a transparent material.

20. The display device according to claim 18, wherein the first portion of the repair part includes a reflective material and is configured to reflect laser light onto the portion of the first branch line, and
wherein the second portion of the repair part includes the reflective material and is configured to reflect the laser light onto the portion of the second branch line.
